(19) United States
(12) Patent Application Publication
(10) Pub. No.: US 2006/0238987 A1
(43) Pub. Date: Oct. 26, 2006

(54) Power supply device, backlight assembly and display apparatus having the same

(75) Inventors: Mun-Soo Park, Gyeonggi-do (KR); Hyeon-Yong Jang, Gyeonggi-do (KR); Timothy Su, Gyeonggi-do (KR)

Correspondence Address: PATENT LAW GROUP LLP, 2635 NORTH FIRST STREET, SUITE 223, SAN JOSE, CA, 95134, US

(73) Assignee: Samsung Electronics Co., LTD.

(21) Appl. No.: 11/351,424

(22) Filed: Feb. 10, 2006

(30) Foreign Application Priority Data
Apr. 22, 2005 (KR) 2005-33524

(51) Int. Cl. H05K 7/00

(52) U.S. Cl. 361/748

(57) ABSTRACT

In a power supply device whose safety is improved, a backlight assembly and a display apparatus having thereof, the power supply device includes a printed circuit board, a transformer and a securing cover. The transformer is disposed on the printed circuit board to change a first input voltage into a second voltage, and outputs the second voltage. The securing cover covers a portion where the second voltage is outputted. Accordingly, when a securing cover covers a portion where the high voltage is outputted, the safety of the power supply can be enhanced.

### CROSS REFERENCE TO RELATED APPLICATIONS

This application claims priority to Korean Patent Application No. 2005-33524 filed on Apr. 22, 2005, the contents of which are herein incorporated by reference in its entirety.

### BACKGROUND OF THE INVENTION

1. Field of the Invention

The present invention relates to a power supply device, a backlight assembly and a display apparatus having the power supply device. More particularly, the present invention relates to a power suppl device having improved safety, a backlight assembly and a display apparatus having the power supply device.

2. Description of the Related Art

Recently, flat display devices, such as a liquid crystal display device, an organic electro luminescence display device, a plasma display panel device, and so on, having thin thickness, light weight and low power consumption, are widely used as a display device of an information processing device.

The liquid crystal display device, one of the above-mentioned flat display devices, includes a liquid crystal display panel displaying an image by using a liquid crystal, and a backlight assembly providing the liquid crystal display panel with light.

The liquid crystal display panel includes two electrodes facing each other to form an electric field, and the liquid crystal layer is disposed between the electrodes. When the electric field is applied to the liquid crystal layer, an arrangement of the liquid crystal layer is altered, and an optical transmittance of the liquid crystal layer is changed. As a result, the liquid crystal display panel transforms light into an image containing information.

The backlight assembly provides the liquid crystal display panel with light. The backlight assembly includes a light source emitting light and a power supply supplying the light source with power. For the power supply, a printed circuit board having a surface mount device (SMD) type transformer is generally used.

Further, for the light source, a cold cathode fluorescent lamp (CCFL), an external electrode fluorescent lamp (EEFL), a flat fluorescent lamp (FFL), a light emitting diode (LED), etc. are generally used.

The backlight assembly employing the EEFL as a light source requires relatively high voltage. Accordingly, such a backlight assembly includes a power supply having a transformer for outputting relatively high voltage.

However, an arc can be produced when the power supply outputs high voltage. Accordingly, there is a problem of a fire.

### SUMMARY OF THE INVENTION

The present invention provides a power supply device having improved safety.

The present invention also provides a backlight assembly having the above power supply device.

The present invention also provides a display apparatus having the above backlight assembly.

In a power supply device according to an example embodiment of the present invention to achieve the above-mentioned purpose, the power supply device includes a printed circuit board, a transformer and a securing cover. The transformer is disposed on the printed circuit board to change a first input voltage into a second voltage, and outputs the second voltage. The securing cover covers a portion where the second voltage is outputted.

In a backlight assembly according to an example embodiment of the present invention, the backlight assembly includes a lamp and a power supply part. The lamp generates light. The power supply part outputs a high voltage to supply the lamp with the high voltage, and has a securing cover to cover a portion where a high voltage is outputted.

In a display apparatus according to an example embodiment of the present invention, the display apparatus includes a backlight assembly and a display panel. The backlight assembly includes a lamp generating light and a power supply part outputting a high voltage to supply the lamp with the high voltage. The power supply part includes a securing cover covering a portion where the high voltage is outputted. The display panel displays an image by using the light generated from the backlight assembly.

Since a securing cover covers a portion where the high voltage is outputted, an electric shock in a human body and a fire caused by an arc can be efficiently prevented. Accordingly, the safety of the power supply device is improved further more.

### BRIEF DESCRIPTION OF THE DRAWINGS

The above and other features and advantages of the present invention will become more apparent by describing in detailed example embodiments thereof with reference to the accompanying drawings, in which:

FIG. 1 is an exploded perspective view showing a backlight assembly according to a first example embodiment of the present invention;

FIG. 2 is a schematic plan view showing a linking relationship between the power supply part and the lamps shown in FIG. 1;

FIG. 3 is an enlarged view showing a portion ‘A’ in FIG. 1;

FIG. 4 is an exploded perspective view showing a power supply part in FIG. 1;

FIG. 5 is an exploded perspective view showing a backlight assembly according to a second example embodiment of the present invention;

FIG. 6 is an exploded perspective view showing a backlight assembly according to a third example embodiment of the present invention; and

FIG. 7 is an exploded perspective view showing a display apparatus according to an example embodiment of the present invention.

### DESCRIPTION OF THE EMBODIMENTS

It should be understood that the example embodiments of the present invention described below may be varied or modified in many different ways without departing from the inventive principles disclosed herein, and the scope of the present invention is therefore not limited to these particular embodiments. Rather, these embodiments are provided so that this disclosure will be thorough and complete, and will fully convey the concept of the invention to those skilled in the art by way of an example and not of limitation.

Hereinafter, the present invention will be explained in detail with reference to the accompanying drawings.

### Example Embodiment 1 of Backlight Assembly

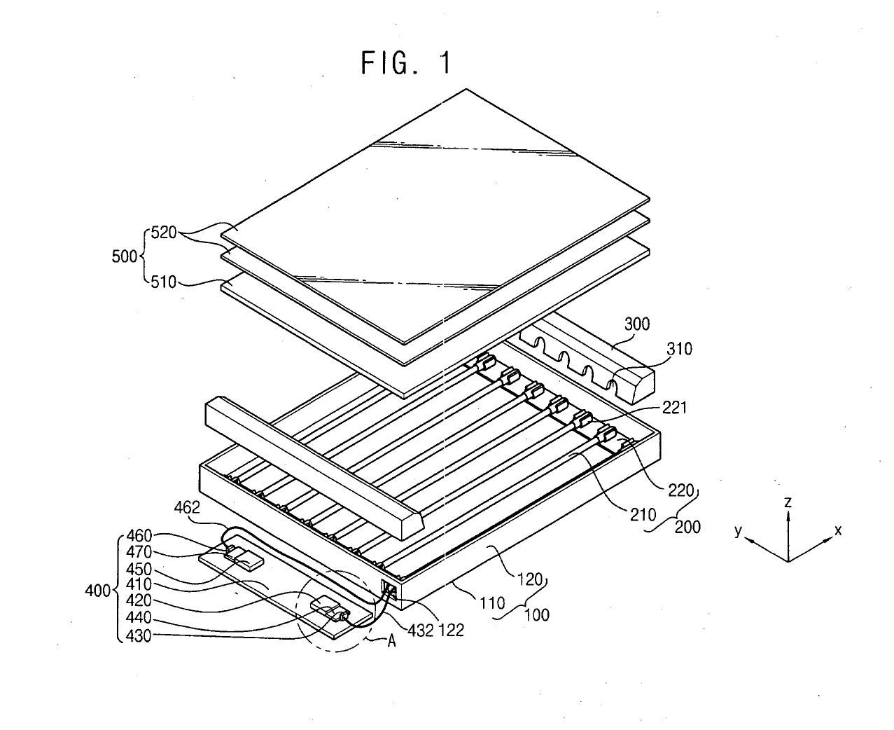

FIG. 1 is an exploded perspective view showing a backlight assembly according to a first example embodiment of the present invention.

Referring to FIG. 1, the backlight assembly includes a receiving container 100, a light-generating unit 200, a mold frame 300, a power supply part 400, and an optical sheet part 500.

The receiving container 100 includes a bottom portion 110 and a sidewall 120 extending from an edge of the bottom portion 110 to define a receiving space. The receiving space receives the light-generating unit 200, the mold frame 300, the power supply part 400, and the optical sheet part 500. A hole 122 is formed at the sidewall 120 so that a wire 432 may pass through the hole 122.

The light-generating unit 200 is positioned in the receiving container 100 and generates light. The light-generating unit 200 includes a plurality of lamps 210 and a power-applying unit 220.

The lamps 210 are disposed over the bottom portion 110 of the receiving container 100 in parallel with each other along a Y-axis. Each of the lamps 210 includes a tube body having a bar-shape, and external electrodes disposed at each of both end portions of the tube body, respectively. Discharging gas is injected into the tube body. When electric power is applied to the discharge gas, the discharge gas generates invisible light. A fluorescent layer is formed on an inside surface of the tube body. The fluorescent layer converts the invisible light into visible light.

The power-applying unit 220 includes a plurality of sockets 221 that are electrically connected to the external electrode of the lamp 210. A pair of power-applying units 220 is disposed at both end portions of the bottom portion 110 along an X-axis.

The power-applying unit 220 receives a driving signal from the power supply part 400, and applies the driving signal to each of the external electrodes of the lamps 210 simultaneously. The external electrodes receiving the driving signal provide the discharging gas with electric power to generate an invisible light, and the invisible light is converted into a visible light by the fluorescent layer formed on the inside surface of the tube body A pair of the mold frames 300 is disposed at both end portions of the bottom portion 110 along an X-axis. The mold frames 300 cover the pair of the power-applying units 220 applying power to the electrode of the lamp 210, respectively.

A vertical cross section of the mold frame 300 has an U-shape, and a plurality of combining holes 310 is formed at a side surface of the mold frame 300. Alternatively, the vertical cross section of the mold frame 300 may have an L-shape.

The power supply part 400 generates a driving power and applies the driving power to drive the lamp 210. The power supply part 400 includes a printed circuit board 410, a transformer, a connector and a securing cover.

The printed circuit board 410 includes a plurality of wirings, and has a plate-shape. The printed circuit board 410 is disposed on an external surface of the bottom portion 110 of the receiving container 100. The transformer includes a first transformer 420 and a second transformer 450. The transformer boosts a low voltage applied from an exterior device to be a high voltage, and then outputs the high voltage. The connector includes a first connector 430 and a second connector 460. The connector receives the high voltage from the first and second transformers 420 and 450, and transmits the high voltage to each of both ends of the power-applying unit 220 through a first wire 432 and a second wire 462. The securing cover includes a first securing cover 440 and a second securing cover 470. The securing cover covers a portion where the high voltage is outputted to prevent an electric shock in the human body and a fire caused by an arc.

The optical sheet part 500 includes a diffusing plate 510 and a prism sheet 520. The diffusing plate 510 is disposed at an upper part of the lamps 210, and diffuses light generated from the lamps 210 to improve brightness uniformity. Both end portions of the diffusing plate 510 are disposed on an upper face of the mold frame 300, or the diffusing plate 510 is disposed over the lamps 210. The prism sheet 520 comprises at least one sheet, and includes a plurality of prism patterns. The prism sheet 520 improves a front-view brightness of light passing through the diffusing plate 510.

The backlight assembly may further include a plurality of the supporters (not shown) and a reflecting plate (not shown).

The supporters are disposed on the bottom portion 110 of the receiving container 100. Each of the supporters includes a lamp-supporting portion and a diffusing-plate-supporting portion. The lamp-supporting portion supports the lamps 210 to prevent drifting of the lamps 210. The diffusing-plate-supporting portion supports the diffusing plate 510 to prevent drifting of the diffusing plate 510.

The reflecting plate is disposed on a front surface of the bottom portion 110 of the receiving container 100 to reflect light that exits from the lamps 210 toward the optical sheet part 500. Alternatively, a metal reflecting layer formed on the bottom portion 110 of the receiving container 100 may substitute for the reflecting plate.

Although FIG. 1 illustrates the light-generating unit 200 as including a plurality of external electrode fluorescent lamps (EEFL) disposed in parallel with each other and simultaneously driven, a flat fluorescent lamp (FFL) may substitute for the EEFL in other embodiments of the present invention. When the light-generating unit 200 is implemented as the FFL, the mold frame 300 and the supporter are not necessary.

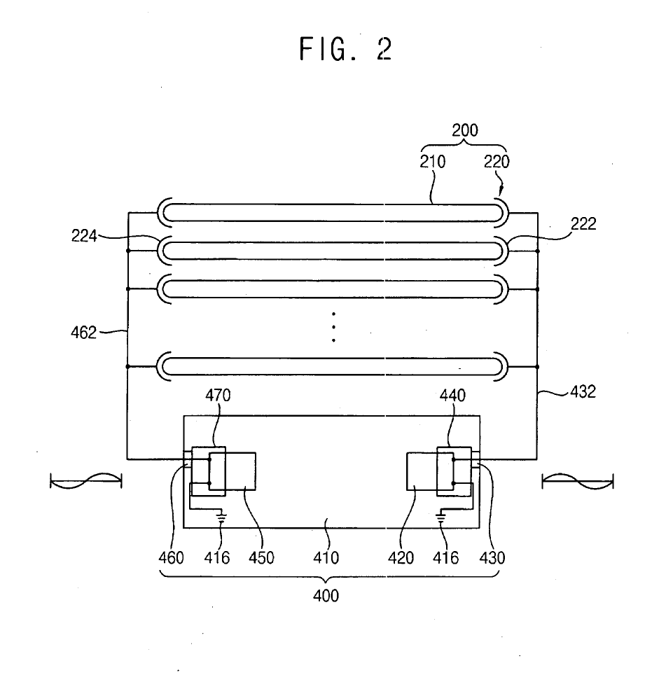

FIG. 2 is a schematic plan view showing a linking relationship between the power supply part and the lamps shown in FIG. 1.

Referring to FIG. 2, the power supply part 400 includes a printed circuit board 410, a transformer, a connector, and a securing cover.

The printed circuit board 410 includes a plurality of wires and a plurality of terminals. The transformer is disposed on the terminals and electrically connected with the wires.

The transformer includes a first transformer 420 and a second transformer 450. The first and second transformers 420 and 450 are disposed on the terminals of the printed circuit board 410. For example, the first and second transformers 420 and 450 are disposed facing each other at both end portions of the printed circuit board 410.

The first transformer 420 includes a first output terminal and a second output terminal. The first transformer 420 outputs a first high voltage through the first output terminal, and outputs a ground voltage through the second output terminal. The second transformer 450 includes a third output terminal and a fourth output terminal. The second transformer 450 outputs a second high voltage through the third output terminal, and outputs a ground voltage through the fourth output terminal. The first and second high voltages oscillate sinusoidally, and the first and second high voltages have a phase difference by about 180 degrees from each other. The second and the fourth output terminals are electrically connected to a ground pattern 416 formed on the printed circuit board 410.

The connector includes a first connector 430 and a second connector 460 disposed on the printed circuit board 410. The first connector 430 is disposed so as to face the first transformer 420 and electrically connected to the first output terminal of the first transformer 420. The first connector 430 is electrically connected with a first end 222 of the light-generating unit 200 through a first wire 432 to apply the first high voltage. The second connector 460 is disposed facing the second transformer 450 and electrically connected to the third output terminal of the second transformer 450. The second connector 460 is electrically connected with a second end 224 of the light-generating unit 200 through a second wire 462 to apply the second high voltage. When the first and second high voltages having a phase difference by about 180 degrees from each other are applied to both ends of the lamps 210, a virtual ground keeping a voltage of zero is formed at a middle portion of the lamps 210.

The securing cover includes a first securing cover 440 and a second securing cover 470 to cover an area where the high voltage is outputted. The first securing cover 440 covers an area where the first high voltage and the ground voltage are outputted, and the second securing cover 470 covers an area where the second high voltage and the ground voltage are outputted. Accordingly, the securing cover prevents a fire caused by an arc due to the high voltage of the transformer, and protects a human from an electric shock.

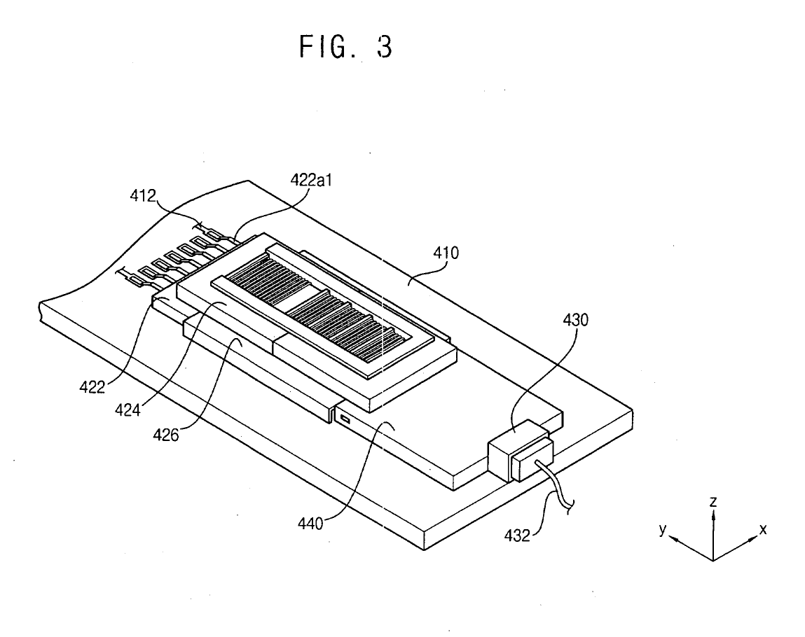

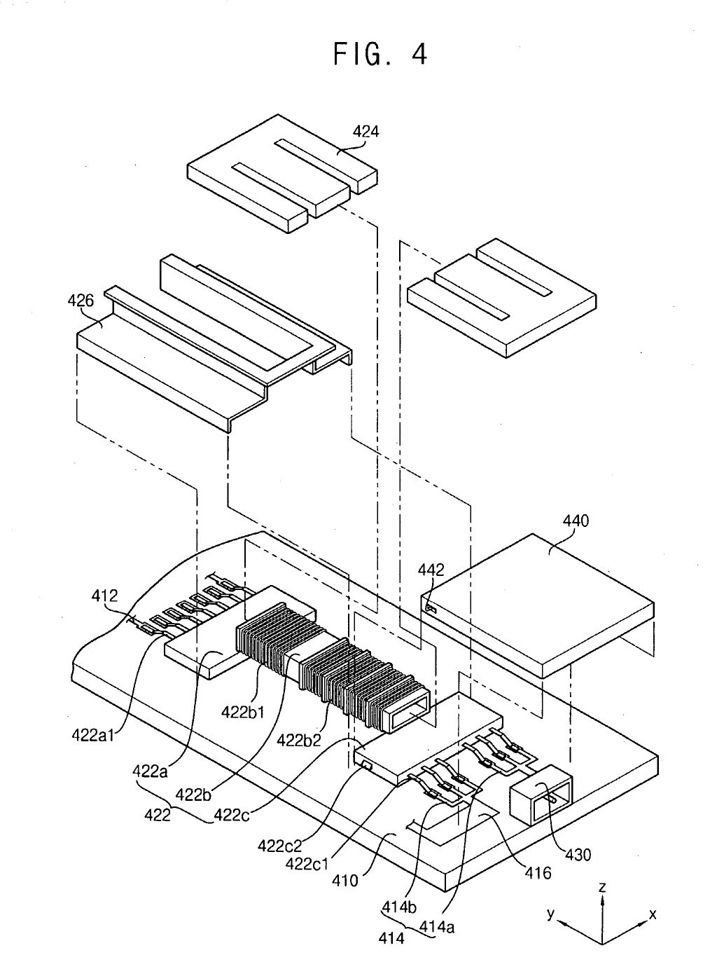

FIG. 3 is an enlarged view showing a portion A in FIG. 1, and FIG. 4 is an exploded perspective view showing a power supply part in FIG. 1.

Referring to FIGS. 3 and 4, the power supply part 400 includes a printed circuit board 410, a transformer 420, a connector 430, and a securing cover 440. Hereinafter, a first transformer 420, a first connector 430, a first wire 432 and a first securing cover 440 will be explained. Since a second transformer 450, a second connector 460, a second wire 462, and a second securing cover 470 are substantially same as the first transformer 420, the first connector 430, the first wire 432, and the first securing cover 440 respectively, an explanation of the second transformer 450, the second connector 460, the second wire 462, and the second securing cover 470 will be omitted.

The printed circuit board 410 has a plate-shape. The printed circuit board 410 includes an input wiring 412 and an output wiring 414 electrically connected to a first transformer 420. The printed circuit board 410 may further include a driving-voltage-generating portion (not shown) generating a low voltage. The printed circuit board 410 may include, for example, an alternating current-to-direct current converting portion, a direct current-to-direct current converting portion, and a direct current-to-alternating current inverting portion.

The first transformer 420 is disposed on the printed circuit board 410 and includes a bobbin 422, a core 424 and an insulating member 426 between the bobbin 422 and the core 424.

The bobbin 422 includes an input portion 422a to which the low voltage is applied, a transforming portion 422b transforming the low voltage to a high voltage, and an output portion 422c outputting the high voltage. The transforming portion 422b is between the input portion 422a and the output portion 422c. The bobbin 422 includes refractory and insulating plastics such as fiber glass for instance.

The input portion 422a has, for example, a hexahedron-shape. The input portion 422a includes a plurality of input terminals 422a1 disposed in parallel with each other along an X-axis. Two outermost input terminals 422a1 are electrically connected to the input wiring 412 to receive the low voltage from the input wiring 412. In detail, the low voltage corresponds to a potential difference between the two outermost input terminals 422a1. The other input terminals 422a1 disposed between the two outermost input terminals 422a1 are fixed to the printed circuit board 410 through soldering to increase bonding strength between the first transformer 420 and the printed circuit board 410.

The transforming portion 422b includes a body portion, a first wire 422b1 and a second wire 422b2. A rectangular perforated hole is formed at the body portion. The first and second wires 422b1 and 422b2 are separated from each other and coil around the body portion. The first wire 422b1 is electrically connected to the input terminal 422a1 of the input portion 422a, and the second wire 422b2 is electrically connected to an output terminal 422c1 of an output portion 422c.

The low voltage applied to the first wire 422b1 is transformed to the high voltage according to a boosting ratio, and the high voltage is generated between both ends of the second wire 422b2. In this case, the boosting ratio varies according to the winding number of the first and second wires 422b1 and 422b2. For example, when the boosting ratio is 1 to 4, the winding number of the second wire 422b2 is four times as many as that of the first wire 422b1.

The output portion 422c has a hexahedron-shape and includes a plurality of output terminals 422c1 electrically connected to the output wiring 414. For example, the output terminals 422c1 are grouped into two sections and disposed in parallel with each other along an X-axis. Each of the two sections includes, for example, three output terminals 422c1. The output portion 422c further includes protrusions 422c2. The protrusions 422c2 are formed at side face of the output portion 422c. The output portion 422c is combined with the first securing cover 440 through the protrusions 422c2. The output wiring 414 includes a high voltage output wiring 414a and a ground voltage output wiring 414b.

A first group of the output terminals 422c1 is electrically connected to the high voltage output wiring 414a. The high voltage output wiring 414a is electrically connected with the first connector 430 to apply the high voltage to the first connector 430. A second group of the output terminals 422c1 is electrically connected to the ground voltage output wiring 414b. The ground voltage output wiring 414b is electrically connected to a ground pattern 416 formed on the printed circuit board 410, and is therefore grounded.

The core 424 includes an iron core, for example, such as ferrite. When an electric current flows through the first wire 422b1 coiling around the bobbin 422, magnetic flux is generated. Then the magnetic flux passes along the core 424, and passes through the second wire 422b2 coiling around the bobbin 422 to induce the high voltage at between both ends of the second wire 422b2.

The insulating member 426 includes, for example, a plastic that is an insulating matter. The insulating member 426 is interposed between the first and second wires 422b1 and 422b2 to electrically insulate the core 424 from the first and second wires 422b1 and 422b2.

The first connector 430 is electrically connected with the high voltage output wiring 414a to receive the high voltage, and provides the power-applying unit 220 with the high voltage through the first wire 432.

The first securing cover 440 is combined with the output portion 422c of the bobbin 422 to cover the output terminals 422c1, the output wiring 414 and a portion of the first connector 430. Alternatively, the first securing cover 440 may cover only the output terminals 422c1, or may cover only the output terminals 422c1 and the output wiring 414.

The first securing cover 440 includes fiber glass having superior incombustibility and insulating properties. For example, the first securing cover 440 meets UL94-V0 incombustibility standard and has a dielectric breakdown voltage above 30 MV/m. Alternatively, the first securing cover 440 may include substantially same material as that of the bobbin 422. In this case, UL94-V0 incombustibility standard means a standard of an extent that a fire of a specimen is extinguished within about 10 seconds by itself when a burner ignites the specimen standing vertically.

The first securing cover 440 includes a cover-bottom portion and three cover-side portions extending from an edge of the cover-bottom portion. Combining holes 442 are formed at the cover-side portions. The combining holes 442 face each other. The combining holes 442 receive the protrusions 422c2 of the output portion 422c to combine the first securing cover 440 with the output portion 422c.

In the first transformer 420, a predetermined space is defined between the output portion 422c of the bobbin 422 and the core 424 by the insulating member 426. The first securing cover 440 is inserted into the space and the insulating member 426 forms the space. In detail, the insulating member 426 has a predetermined thickness to define the space between the output portion 422c and the core 424, and then an end portion of the first securing cover 440 is inserted into the space.

As described above, when the first securing cover 440 covers a portion where the high voltage is outputted, so that an electric shock in a human body and a fire caused by an arc that is generated at the output portion of the transformer, may be prevented.

### Example Embodiment 2 of Backlight Assembly

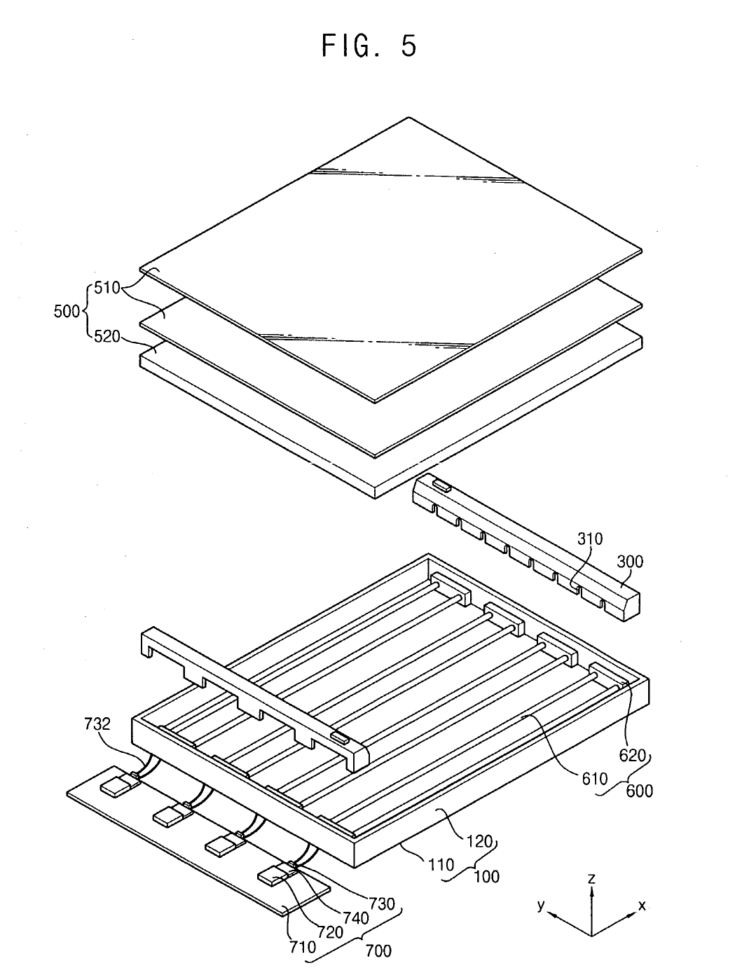

FIG. 5 is an exploded perspective view showing a backlight assembly according to a second example embodiment of the present invention. Hereinafter, the same reference numerals will be used at substantially same elements as those in FIG. 1.

Referring to FIG. 5, the backlight assembly includes a receiving container 100, a light-generating unit 600, a mold frame 300, a power supply part 700, and an optical sheet part 500.

The receiving container 100 includes a bottom portion 110 and a sidewall 120 to define a receiving space. The receiving space receives the light-generating unit 600, the mold frame 300, the power supply part 700 and the optical sheet part 500.

The light-generating unit 600 is disposed in the receiving container 100 to generate light, and includes a plurality of lamps 610 and a plurality of lamp holders 620.

The lamps 610 are disposed in the receiving container 100 in parallel with each other along a Y-axis. Each of the lamps 610 includes a tube body having a bar-shape, and internal electrodes disposed at inside of end portions of the tube body, respectively. A discharging gas is injected into the tube body to generate an invisible light, and a fluorescent layer is formed on an inside surface of the tube body to convert the invisible light into a visible light.

The lamp holders 620 cover both end portions of the tube body to fix the tube body. For example, one lamp holder 620 covers the end portions of two lamps 610 to fix the lamps 610.

A pair of the mold frame 300 is disposed on both side portions of the bottom portion 110 of the receiving container 100 along an X-axis to cover the lamp holders 620 covering both ends of the lamps 610. A vertical cross section of the mold frame 300 has an U-shape. A plurality of lamp-combining holes 310 is formed at a side surface of the mold frame 300.

The power supply part 700 generates driving powers to drive the lamps 610 individually. The power supply part 700 includes a printed circuit board 710, a plurality of transformers 720, a plurality of connectors 730, and a plurality of securing covers 740.

The printed circuit board 710 includes a plurality of wirings, and has a plate-shape. The printed circuit board 710 is disposed on an external surface of the bottom portion 110 of the receiving container 100.

The transformers 720 boost a first voltage provided from an exterior into a second voltage, and then output the second voltage.

The connectors 730 are formed as many as the transformers 720. The connectors 730 receive the second voltage from transformers, and transmit the second voltage to the lamps 610 through a plurality of wires 732.

The securing covers 740 are formed as many as the transformers 720. The securing covers 740 cover each of portions where the second voltages are output to prevent an electric shock of a human body and a fire caused by an arc.

The optical sheet part 500 is disposed at an upper part of the lamps 610. The optical sheet part 500 includes a diffusing plate 510 diffusing light and a prism sheet 520 that improves a front-view brightness.

As described above, the securing covers 740 cover portions where the second voltages are outputted, so that an electric shock in a human body and a fire caused by an arc that is generated at the output portions of the transformers 720, may be prevented.

### Example Embodiment 3 of Backlight Assembly

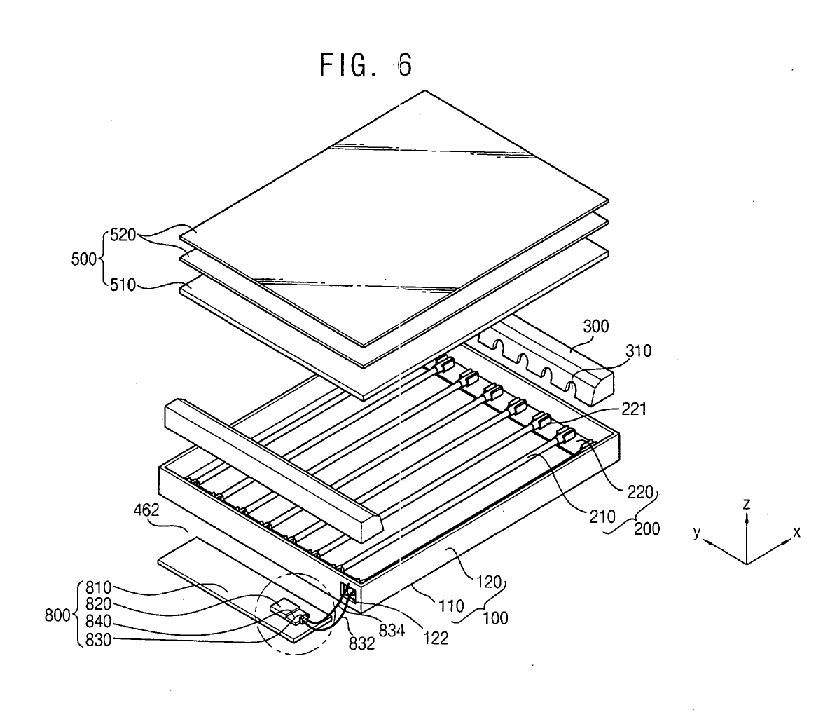

FIG. 6 is an exploded perspective view showing a backlight assembly according to a third example embodiment of the present invention. Hereinafter, the same reference numerals will be used to refer to the same or like parts as those described in FIG. 1.

Referring to FIG. 6, the backlight assembly includes a receiving container 100, a light-generating unit 200, a mold frame 300, a power supply part 800, and an optical sheet part 500.

The receiving container 100 includes a bottom portion 110 and a sidewall 120 to define a receiving space. The receiving space receives the light-generating unit 200, the mold frame 300, the power supply part 800 and the optical sheet part 500. A hole 122 is formed on the sidewall 120, and wires 832 and 834 are passed through the hole 122.

The light-generating unit 200 is disposed in the receiving container 100, and generates light. The light-generating unit 200 includes a plurality of lamps 210 and a power-applying unit 220.

The lamps 210 are disposed in the receiving container 100 in parallel with each other along a Y-axis. Each of the lamps 210 includes a tube body having a bar-shape, and external electrodes disposed at end portions of the tube body, respectively. Discharging gas is injected into the tube body to generate an invisible light by discharging, and a fluorescent layer is formed on an inside surface of the tube body to convert the invisible light into a visible light.

The power-applying unit 220 includes a plurality of sockets 221. The power-applying unit 220 is combined with the external electrode of the lamp 210 through the sockets 221. A pair of power-applying units 220 is disposed on end portions of the bottom portion 110 along an X-axis, respectively. The power-applying unit 220 receives a driving signal from the power supply part 800, and applies the driving signal to each of the external electrodes of the lamps 210 simultaneously.

A pair of the mold frames 300 is disposed on both side portions of the bottom portion 110 along an X-axis to cover a pair of the power-applying units 220 applying power to the external electrode of the lamp 210, respectively.

The power supply part 800 generates a driving power to drive the lamp 210. The power supply part 800 includes a printed circuit board 810, a transformer 820, a connector 830, and a securing cover 840.

The printed circuit board 810 includes a plurality of wirings, and has a plate-shape. The printed circuit board 810 is disposed on an external surface of the bottom portion 110 of the receiving container 100. The transformer 820 boosts a first voltage provided from an exterior into a second voltage, and then outputs the second voltage. The connector 830 receives the second voltage from the transformer 820 and transmits the second voltage to the power-applying unit 220 through a first wire 832 and a second wire 834. The first wire 832 applies the second voltage to a side portion of the power-applying unit 220, and the second wire 834 applies a ground voltage to the other side portion of the power-applying unit 220. The securing cover 840 covers a portion where the second voltage is outputted to prevent an electric shock in a human body and a fire caused by an arc.

The optical sheet part 500 includes a diffusing plate 510 and at least a prism sheet 520. The diffusing plate 510 is disposed at an upper part of the lamps 210, and diffuses light generated from the lamps 210 to improve uniformity of brightness.

### Example Embodiment of Display Apparatus

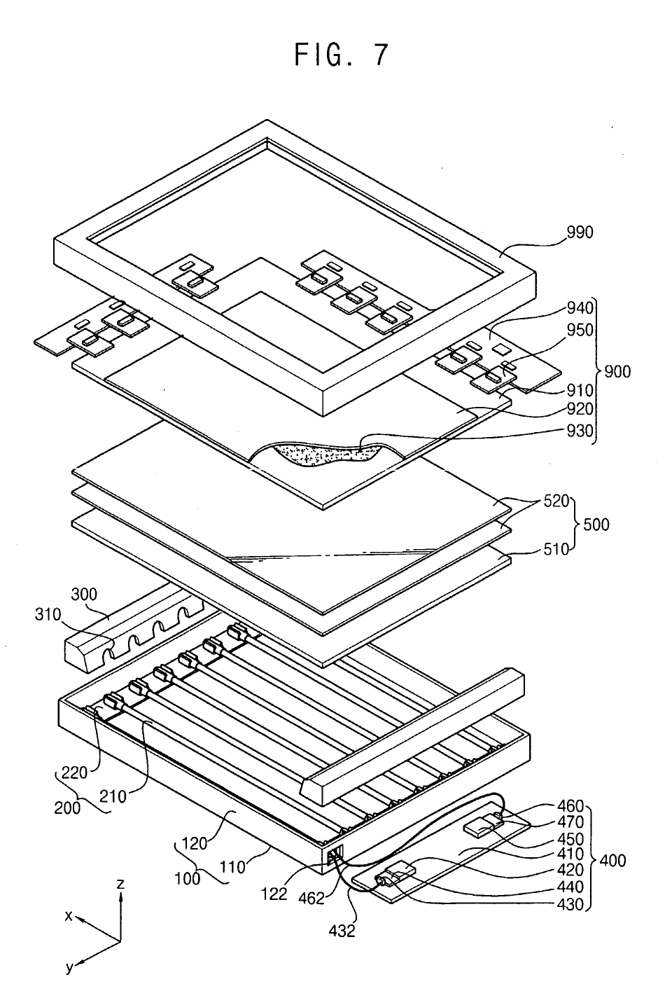

FIG. 7 is an exploded perspective view showing a display apparatus according to an example embodiment of the present invention. Hereinafter, the same reference numerals will be used to refer to the same or like parts as those described in FIGS. 1 to 3 and any further repetitive explanations concerning the above elements will be omitted.

Referring to FIG. 7, the display apparatus includes a backlight assembly, a display panel 900 and a top chassis 990.

The display panel 900 is disposed over the backlight assembly to transform light generated from the backlight assembly into an image light containing information. The display panel 900 includes a first substrate 910, a second substrate 920, a liquid crystal layer 930, a driving circuit substrate 940, and a flexible printed circuit board 950.

The first substrate 910 includes a plurality of pixel electrodes arranged in a matrix-shape, a plurality of thin film transistors (TFTs) applying a driving voltage to the pixel electrodes, respectively, and a plurality of signal lines for operating the TFTs.

The pixel electrodes include an optically transparent and electrically conductive material such as Indium tin oxide (ITO), indium zinc oxide (IZO), amorphous indium tin oxide (a-ITO), etc. Each of the pixel electrodes is patterned by, for example, a photo etching process.

The second substrate 920 faces the first substrate 910. The second substrate 920 includes a common electrode and a plurality of color filters facing the pixel electrodes, respectively. The common electrode includes an optically transparent and electrically conductive material.

The color filter includes a red color filter selectively transmitting red light, a green color filter selectively transmitting green light, and a blue color filter selectively transmitting blue light.

The liquid crystal layer 930 is disposed between the first substrate 910 and the second substrate 920. Liquid crystal molecules of the liquid crystal layer 930 are realigned according to an electric field generated between the pixel electrode and the common electrode. An optical transmittance of light generated from the backlight assembly is adjusted according to an alignment of the liquid crystal molecules that are realigned, and then the light whose optical transmittance is adjusted passes through the color filters to display an image.

The driving circuit substrate 940 includes a driving circuit unit processing an image signal. The driving circuit unit converts an image signal externally provided into a driving signal controlling the TFT.

The flexible printed circuit board 950 electrically connects the driving circuit substrate 940 with the first substrate 910 to provide the first substrate 910 with the driving signal generated from the driving circuit substrate 940. The flexible printed circuit board 950 is folded to dispose the driving circuit substrate 940 at a side portion or a bottom portion of the display panel 900.

The top chassis 990 covers an edge of the display panel 900, and is combined with a side portion 120 of the receiving container 100 to secure the display panel 900 to an upper part of the backlight assembly. The top chassis 990 protects the display panel 900 from an exterior shock or a vibration, and also prevents the display panel 900 from being separated from the receiving container 100.

As described above, the securing cover covers a portion where the high voltage is outputted, so that an electric shock in a human body and a fire caused by an arc, are prevented. As a result, the safety of the power supply is enhanced.

Having described the example embodiments of the present invention and its advantages, it is noted that various changes, substitutions and alterations can be made herein without departing from the spirit and scope of the invention as defined by appended claims.

What is claimed is:

1. A power supply device comprising:
a printed circuit board;
a transformer disposed on the printed circuit board to convert a first input voltage into a second voltage and to output the second voltage; and
a securing cover covering a portion where the second voltage is outputted.

2. The power supply device of claim 1, wherein the second voltage is higher than the first voltage.

3. The power supply device of claim 1, wherein the transformer comprises an output terminal outputting the second voltage, the printed circuit board comprises an output wiring electrically connected to the output terminal and a connector electrically connected to the output wiring, and the securing cover covers the output terminal, the output wiring and a portion of the connector.

4. The power supply device of claim 1, wherein the transformer comprises an output terminal outputting the second voltage, and the securing cover covers the output terminal.

5. The power supply device of claim 1, wherein the transformer comprises an output terminal outputting the second voltage, the printed circuit board comprises an output wiring electrically connected to the output terminal, and the securing cover covers the output terminal and the output wiring.

6. The power supply device of claim 1, wherein the transformer comprises a bobbin, a core and an insulating member between the bobbin and the core, the bobbin comprises an input portion, an output portion and an transforming portion between the input portion and the output portion, the output portion comprises a protrusion, and the securing cover comprises a combining hole receiving the protrusion of the output portion to combine the securing cover with the output portion.

7. The power supply device of claim 6, wherein the output portion has a pair of protrusions formed at both side surfaces of the output portion, and the securing cover has a pair of combining holes formed at both sidewalls of the securing cover, the pair of combining holes receiving the pair of protrusions.

8. The power supply device of claim 1, wherein the transformer comprises a bobbin, a core and an insulating member between the bobbin and the core, the bobbin includes an input portion, an output portion, and an transforming portion between the input portion and the output portion, a predetermined space is defined between the output portion and the core, and an end portion of the securing cover is inserted into the space.

9. The power supply device of claim 8, wherein the space is defined by the insulating member.

10. The power supply device of claim 1, wherein the securing cover comprises fiber glass.

11. A backlight assembly comprising:
a lamp generating light; and
a power supply part outputting a high voltage to supply the lamp with the high voltage, the power supply port having a securing cover to cover a portion where the high voltage is outputted.

12. The backlight assembly of claim 11, wherein the power supply part comprises:
a printed circuit board;
a transformer disposed on the printed circuit board to convert a low input voltage into the high voltage and to output the high voltage; and
a securing cover covering a portion where the high voltage is outputted.

13. The backlight assembly of claim 12, wherein the transformer applies the high voltage to both end portions of the lamps to drive the lamps simultaneously.

14. The backlight assembly of claim 12, wherein the transformer comprises a first transformer outputting a first high voltage and a second transformer outputting a second high voltage, and the first and second transformers apply the first and second high voltages to both end portions of the lamp to drive the lamp.

15. The backlight assembly of claim 14, wherein the first high voltage and the second high voltage oscillate sinusoidally, and the first and second high voltages have a phase difference by about 180 degrees from each other.

16. The backlight assembly of claim 14, wherein the lamp comprises a plurality of lamps, and the first and second transformers apply the first and second high voltages simultaneously to both end portions of the plurality of lamps to drive the lamps in parallel.

17. The backlight assembly of claim 14, wherein the lamp corresponds to a planar light source device generating substantially planar light, and the first and second transformers apply the first and second high voltages to both end portions of the planar light source device, respectively, to drive the planar light source device.

18. The backlight assembly of claim 12, wherein the lamp comprises a plurality of lamps, and the transformer comprises a plurality of transformers to drive the plurality of lamps.

19. A display apparatus comprising:
a backlight assembly including:
a lamp generating light; and
a power supply part outputting a high voltage to supply the lamp with the high voltage, the power supply part including a securing cover covering a portion where the high voltage is outputted; and
a display panel displaying an image by using the light generated from the backlight assembly.

20. The display apparatus of claim 19, wherein the power supply part includes:
a printed circuit board;
a transformer disposed on the printed circuit board to change a low input voltage into the high voltage and to output the high voltage; and
a securing cover covering a portion where the high voltage is outputted.
